(19) United States
(12) Patent Application Publication
(10) Pub. No.: US 2009/0051656 A1
(43) Pub. Date: Feb. 26, 2009

(54) CAPACITANCE/VOLTAGE CONVERTING CIRCUIT, INPUT APPARATUS USING THE SAME, ELECTRONIC DEVICE, AND CAPACITANCE/VOLTAGE CONVERTING METHOD

(75) Inventor: Koichi Saito, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 11/908,256

(22) PCT Filed: Mar. 8, 2006
(86) PCT No.: PCT/JP2006/304469

§ 371 Date: Sep. 10, 2007

(30) Foreign Application Priority Data
Mar. 8, 2005 (JP) 2005-063512

(51) Int. Cl. G06F 3/02; G01R 27/26

(52) U.S. Cl. 345/168; 324/679

(57) ABSTRACT

A capacitance/voltage conversion circuit converts the difference in electrostatic capacitance between a first capacitor and a second capacitor into a voltage. With such an arrangement, a first voltage applying unit applies a power supply voltage Vdd to the first capacitor during a first state, and applies the ground voltage 0V to the first capacitor during a second state. A second voltage applying unit applies the ground voltage 0V to the second capacitor during the first state, and applies the power supply voltage Vdd to the second capacitor during the second state. A first sample hold circuit averages the voltage at the first capacitor and the voltage at the second capacitor in the first state by turning on a first switch and a second switch, and holds the voltage thus averaged as a first detection voltage Vdet1. In the same way, a second sample hold circuit averages the voltage at the first capacitor and the voltage at the second capacitor in the second state, and holds the voltage thus averaged as a second detection voltage Vdet2. An amplification unit performs differential amplification for the first detection voltage Vdet1 and the second detection voltage Vdet2.

### BACKGROUND OF THE INVENTION

1. Field of the Invention

The present invention relates to a capacitance/voltage conversion circuit used for measurement of electrostatic capacitance.

2. Description of the Related Art

In recent years, electronic devices such as computers, cellular phone terminals, PDAs (Personal Digital Assistants), etc., which have become mainstream, include an input device that allows a user to operate the electronic device by applying pressure with the user's finger. Examples of such known input devices include a joystick, a touch pad, etc.

The input device includes a pair of electrodes provided such that they face one another. With such an input device, upon application of the pressure, the distance between the pair of electrodes changes, leading to a change in the electrostatic capacitance. Such an arrangement provides a function of detecting and analyzing the input operation from the user using a mechanism in which the electrostatic capacitance changes according to the user's input operation. For example, Patent document 1 discloses an input device that employs such a mechanism in which the electrostatic capacitance changes according to the user's input operation.

### [Patent Document 1]

Japanese Patent Application Laid-open No. 2001-325858

The input device that employs the mechanism in which the electrostatic capacitance changes according to the user's input operation includes a capacitance/voltage conversion circuit which converts the electrostatic capacitance into the voltage, thereby detecting the change in electrostatic capacitance in the form of change in voltage. With such an arrangement, such application of the pressure to the pair of the electrodes causes an extremely small change in the electrostatic capacitance, e.g., several pF or less. Accordingly, the performance of the input device is heavily dependent upon the detection sensitivity of the capacitance/voltage conversion circuit. In order to increase the change in the electrostatic capacitance, the area of the electrodes can be increased, which is readily conceived. However, such an arrangement leads to an increased size of the input device.

### SUMMARY OF THE INVENTION

The present invention has been made in view of such a problem. Accordingly, it is a general purpose of the present invention to provide a capacitance/voltage conversion circuit having a function of detecting a minute change in the electrostatic capacitance.

An embodiment of the present invention relates to a capacitance/voltage conversion circuit. The capacitance/voltage conversion circuit, which converts the difference in electrostatic capacitance between a first capacitor and a second capacitor into a voltage, comprises: a first voltage applying unit which applies a predetermined first fixed voltage to the first capacitor during a first state, and which applies a predetermined second fixed voltage, which is lower than the first fixed voltage, to the first capacitor during a second state; a second voltage applying unit which applies the second fixed voltage to the second capacitor during the first state, and which applies the first fixed voltage to the second capacitor during the second state; a first sample hold circuit which averages the voltage at the first capacitor and the voltage at the second capacitor in the first state, and which holds the voltage thus averaged as a first detection voltage; a second sample hold circuit which averages the voltage at the first capacitor and the voltage at the second capacitor in the second state, and which holds the voltage thus averaged as a second detection voltage; and an amplification unit which amplifies the voltage difference between the first detection voltage and the second detection voltage.

With such an embodiment, there is a difference in voltage applied to the capacitor between the first capacitor and the second capacitor, and between the first state and the second state. Then, the difference in the average voltage between the first state and the second state is amplified, thereby amplifying the difference in capacitance between these two capacitors. Such an arrangement enables a minute difference in electrostatic capacitance to be detected.

Also, the amplification unit may be a differential amplifier which receives the first detection voltage and the second detection voltage as the input signals. With such an arrangement, differential amplification is performed for the first detection voltage and the second detection voltage. Such an arrangement cancels the common mode noise, thereby properly detecting the difference in electrostatic capacitance.

Also, each of the first and the second sample hold circuits may have a function of connecting the terminals of the first capacitor and the second capacitor to each other. With such an arrangement, upon connecting the terminals of the first capacitor and the second capacitor to each other, a current path is formed between the first capacitor and the second capacitor, which allows the charge to flow therethrough, thereby averaging the voltages at these two capacitors.

Also, the second fixed voltage may be the ground voltage.

Also, the capacitance/voltage conversion circuit may be integrated formed on a single semiconductor integrated circuit. Examples of arrangements integrally formed include: an arrangement in which all the components of a circuit are formed on a semiconductor substrate; an arrangement in which principal components of a circuit are integrally formed. With such an arrangement, adjusting components for adjusting circuit constants, such as a part of resistors, capacitors, etc., may be provided in the form of external components of the semiconductor substrate. With such an arrangement, the capacitance/voltage conversion circuit is integrally formed in the form of a single LSI, thereby reducing the circuit area.

Another embodiment of the present invention relates to an input device. The input device comprises: a first electrode pair and a second electrode pair each of which includes a pair of electrodes provided such that they face one another, and each of which has a mechanism whereby, upon application of pressure externally, the distance between the two electrodes changes, thereby exhibiting a change in electrostatic capacitance; and the aforementioned capacitance/voltage conversion circuit which converts into a voltage the difference in electrostatic capacitance between the first electrode pair that serves as the first capacitor and the second electrode pair that serves as the second capacitor.

With such an arrangement, in a case that there is a change in the electrostatic capacitance of at least one of the first electrode pair and second electrode pair due to the pressure applied externally, the difference in electrostatic capacitance between these two electrode pairs is amplified. Such an arrangement provides a high-sensitive input device having a function of detecting the electrode pair to which pressure has been applied, and a function of detecting the magnitude of the pressure thus applied.

Yet another embodiment of the present invention also relates to an input device. The input device comprises: a first electrode pair, a second electrode pair, a third electrode pair, and a fourth electrode pair, each of which includes a pair of electrodes provided such that they face one another, and each of which has a mechanism whereby, upon application of pressure externally, the distance between the two electrodes changes, thereby exhibiting a change in electrostatic capacitance; the aforementioned first capacitance/voltage conversion circuit which converts into a voltage the difference in electrostatic capacitance between the first electrode pair that serves as the first capacitor and the second electrode pair that serves as the second capacitor; the aforementioned second capacitance/voltage conversion circuit which converts into a voltage the difference in electrostatic capacitance between the third electrode pair that serves as the first capacitor and the fourth electrode pair that serves as the second capacitor; and a cover which is provided so as to cover the first electrode pair through the fourth electrode pair, and which has a configuration that allows a user to press the cover externally. With such an arrangement, the first electrode pair through the fourth electrode pair are provided at four positions that correspond to the upper portion, the lower portion, the left portion, and the right portion.

With such an embodiment, upon the user pressing any portion in the cover, the electrostatic capacitance changes with respect to the corresponding one from among the first electrode pair through the fourth electrode pair. With such an arrangement, the pressure applied to the upper side and the lower side can be detected by detecting the change in the electrostatic capacitance between the first electrode pair and the second electrode pair. Also, the pressure applied to the left side and the right side can be detected by detecting the change in the electrostatic capacitance between the third electrode pair and the fourth electrode pair.

Yet another embodiment of the present invention also relates to an input device. The input device comprises: multiple electrode pairs each of which includes a pair of electrodes provided such that they face one another, and each of which has a mechanism whereby, upon application of pressure externally, the distance between the two electrodes changes, thereby exhibiting a change in electrostatic capacitance; multiple reference capacitors which are each provided to the multiple electrode pairs, and each of which has a fixed electrostatic capacitance; and the aforementioned multiple capacitance/voltage conversion circuits each of which is provided to a corresponding capacitor pair including the electrode pair and the reference capacitor, and each of which converts into a voltage the difference in electrostatic capacitance between the electrode pair that serves as the first capacitor and the reference capacitor that serves as the second capacitor.

With such an embodiment, the reference capacitors, each of which has a fixed electrostatic capacitance, are each provided to the electrode pairs. With such an arrangement, the difference in electrostatic capacitance is detected between each electrode pair and the corresponding reference capacitor. Such an arrangement provides a function of detecting the electrode pair to which pressure has been applied, and a function of detecting the magnitude of the pressure thus applied, with high sensitivity.

Also, the number of the capacitor pairs, each of which includes the electrode pair and the reference capacitor, may be four. Also, the four capacitor pairs may be provided at four portions that correspond to the upper portion, the lower portion, the left portion, and the right portion. Also, the input device may further include a cover provided so as to cover the four capacitor pairs, and which has a configuration that allows a user to press the cover externally. Such an input device provides: a function of detecting the portion, to which pressure has been applied, from among the upper portion, the lower portion, the left portion, and the right portion; and a function of detecting the magnitude of the pressure thus applied, with high sensitivity.

Also, the capacitor pairs, each of which includes the electrode pair and the reference capacitor, may be disposed in the form of a matrix. Also, the input device may further include a cover provided so as to cover the multiple capacitor pairs, and which has a configuration that allows a user to press the cover externally.

With such an arrangement, the capacitor pairs are disposed in the form of a matrix, thereby providing a touch pad type input device.

Yet another embodiment of the present invention relates to an electronic device. The electronic device comprises the aforementioned input device.

Yet another embodiment of the present invention relates to a capacitance/voltage conversion method. The capacitance/voltage conversion method comprises: a first step in which a first capacitor is charged with a first fixed voltage, and a second capacitor is charged with a second fixed voltage; a step in which the voltage at the first capacitor and the voltage at the second capacitor in the first step are averaged, and the voltage thus averaged is held as a first detection voltage; a second step in which the first capacitor is charged with the second fixed voltage, and the second capacitor is charged with the first fixed voltage; a step in which the voltage at the first capacitor and the voltage at the second capacitor in the second step are averaged, and the voltage thus averaged is held as a second detection voltage; and a step for amplifying the difference between the first detection voltage and the second detection voltage.

With such an embodiment, there is a difference in voltage applied to the capacitor between the first capacitor and the second capacitor, and between the first state and the second state. Then, the difference in the average voltage between the first state and the second state is amplified, thereby amplifying the difference in capacitance between these two capacitors. Such an arrangement enables a minute difference in electrostatic capacitance to be detected.

Also, an arrangement may be made in which the charge stored in the two capacitors is averaged, thereby averaging the voltage at the first capacitor and the voltage at the second capacitor. Also, the second fixed voltage may be the ground voltage.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram which shows a cellular phone terminal which mounts a capacitance/voltage conversion circuit according to a first embodiment.

FIG. 2 is a cross-sectional view taken along line A-A′ of FIG. 1 showing the input device.

FIG. 3 is a circuit diagram which shows a configuration of the capacitance/voltage conversion circuit according to the first embodiment.

FIG. 4 is an operation waveform diagram for the capacitance/voltage conversion circuit shown in FIG. 3.

FIG. 5 is a diagram which shows a configuration of an input device according to a second embodiment.

FIG. 6 is a diagram which shows a layout of capacitor pairs of an input device according to a third embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

### First Embodiment

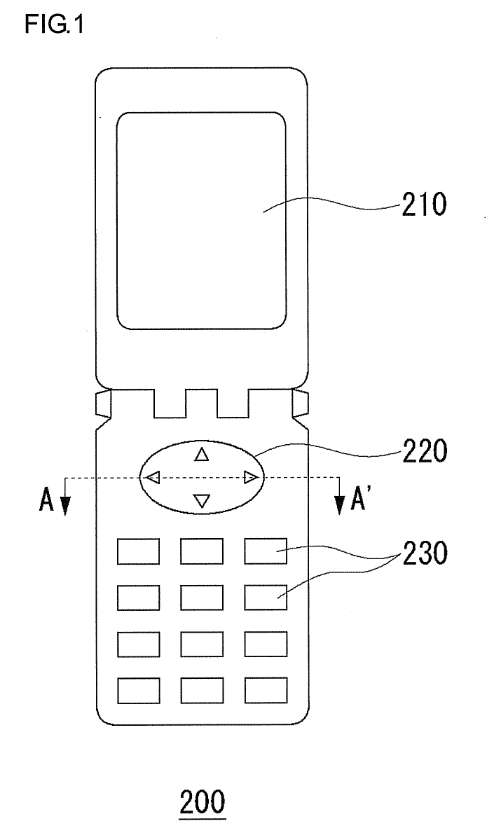

FIG. 1 is a diagram which shows a cellular phone terminal mounting an input device according to a first embodiment. A cellular phone terminal 200 includes a display 210, an input device 220, and operation buttons 230.

The display 210 displays various kinds of information necessary for the user. The input device 220 is an joystick type input device that allows the user to performs input operation with the user's fingers. Specifically, the input device 220 is mounted in order to provide a function that allows the user to select a desired item or object, and a function that supports character input operation, which operates according to the pressure applied by the user to a desired side selected from among the upper side, the left side, the lower side, and the right side.

The operation buttons are an input device which allows the user to input a phone number for a call, and which allows the user to input text.

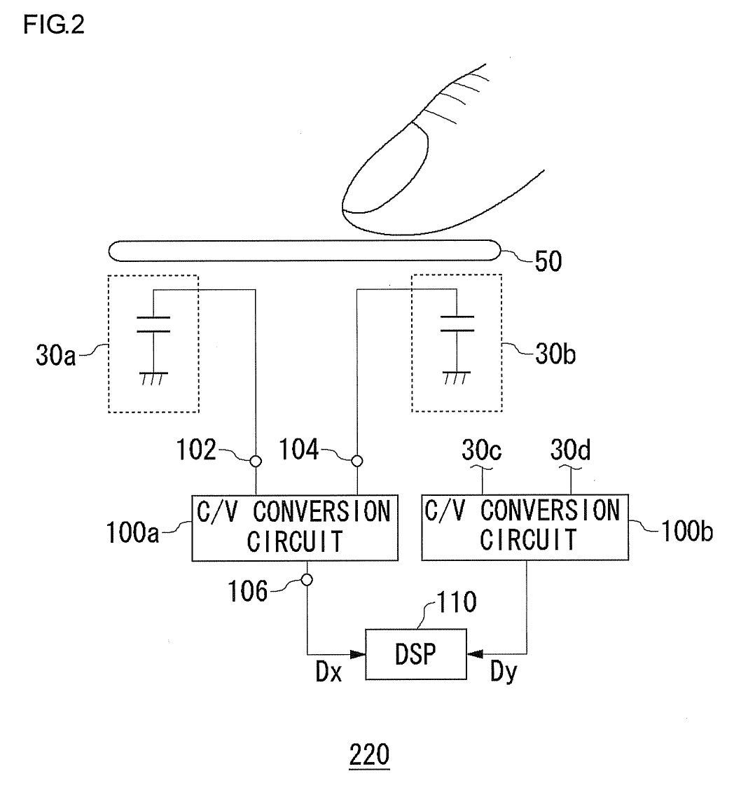

FIG. 2 is a cross-sectional view taken along line A-A′ of FIG. 1 showing the input device 220. The input device 220 includes: four variable capacitance elements 30a through 30d, which will be collectively referred to as “variable capacitance elements 30”; a capacitance/voltage conversion circuits 100a and 100b; and a DSP (Digital Signal Processor) 110. With the present embodiment, the capacitance/voltage conversion circuits 100a and 100b are integrally provided in the form of a single semiconductor integrated circuit.

The variable capacitance elements 30a through 30d are provided at four positions in the input device 220, which corresponds to the upper position, the lower position, the left position, and the right position, respectively. FIG. 2 shows the two variable capacitance elements 30a and 30b that correspond to the left position and the right position, respectively. A cover 50 is formed of an insulating material such as rubber, plastic, or the like, and is provided so as to cover the variable capacitance elements 30a through 30d. With such an arrangement, upon the user pressing the cover 50 with the finger, the pressure is applied to the variable capacitance element 30 provided at the back of the cover 50, which corresponds to the position at which the pressure has been applied.

Each variable capacitance element 30 comprises a pair of electrodes provided such that they face one another. The electrode pair has a capacitor structure, which exhibits the electrostatic capacitance which is determined based upon the area of the electrode pair and the distance between the electrodes. Upon application of the pressure to the top face of the variable capacitance element 30, the distance between the electrodes changes, leading to change in the electrostatic capacitance.

Now, let us consider a case in which the user presses the right side of the cover 50. In this case, the electrostatic capacitance of the variable capacitance element 30b increases. On the other hand, there is no change in the electrostatic capacitance of the variable capacitance element 30a which is at the opposite side to the part at which the pressure has been applied.

The capacitance/voltage conversion circuit 100a detects the difference in the electrostatic capacitance between the variable capacitance elements 30a and 30b disposed at positions opposite to one another, thereby detecting the direction to which the pressure is applied, which is selected from the left side and the right side of the cover 50. The capacitance/voltage conversion circuit 100a outputs, to the downstream DSP 110 in the form of digital data Dx, information which indicates the direction to which the pressure has been applied, which has been selected from the left side and the right side of the cover 50, and the information which indicates the magnitude of the pressure. The DSP 110 is a digital circuit which centrally controls the overall cellular phone terminal 200.

In the same way as described above, the capacitance/voltage conversion circuit 100b detects the difference in the electrostatic capacitance between the two variable capacitance elements 30c and 30d, which forms another capacitor pair. Thus, the capacitance/voltage conversion circuit 100b detects the direction to which the pressure has been applied, which is selected from the upper side and the lower side of the cover 50, and the magnitude of the pressure thus applied. The capacitance/voltage conversion circuit 100b outputs the information to the DSP 110 in the form of digital data Dy.

The DSP 110 combines the digital data sets Dx and Dy output from the capacitance/voltage conversion circuits 100a and 100b, and calculates the direction to which the user has applied the pressure, in a range of 360°.

The capacitance/voltage conversion circuits 100a and 100b have the same configuration. Accordingly, description will be made below regarding the capacitance/voltage conversion circuit 100a as an example.

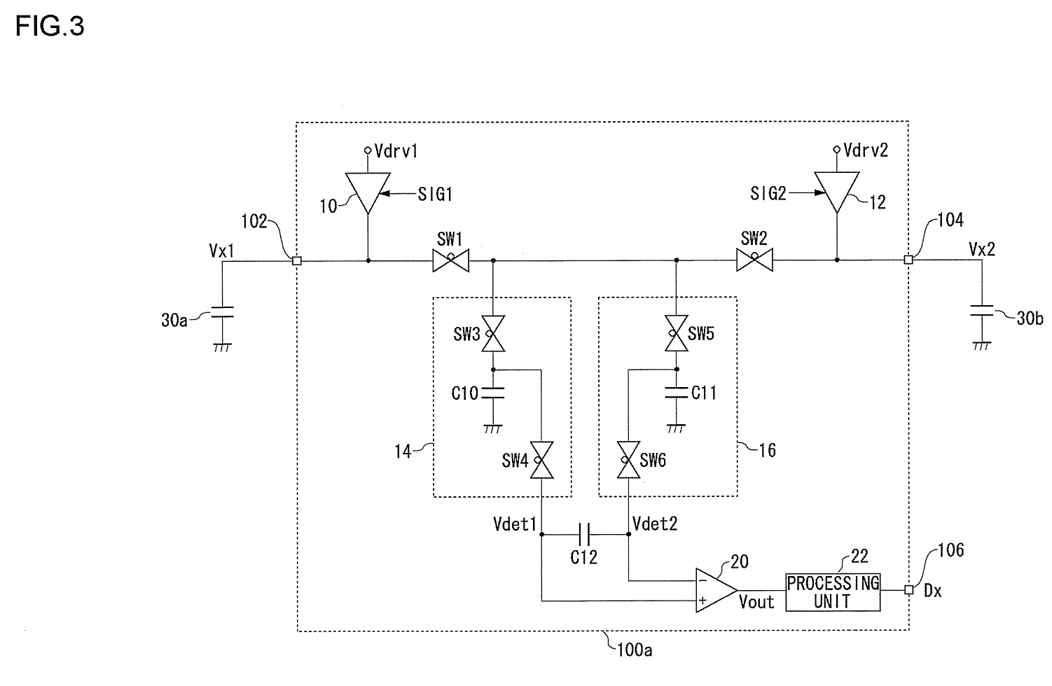

FIG. 3 is a circuit diagram which shows a configuration of the capacitance/voltage conversion circuit 100a according to the present embodiment.

The capacitance/voltage conversion circuit 100a includes input/output terminals, i.e., a first detection terminal 102, a second detection terminal 104, and an output terminal 106. The capacitance/voltage conversion circuit 100a converts the difference in the electrostatic capacitance between a first capacitor connected to the first detection terminal 102 and a second capacitor connected to the second detection terminal 104, and outputs the voltage thus converted to the DSP 100 via the output terminal 106.

With the present embodiment, the first capacitor and the second capacitor thus connected to the detection terminals correspond to the variable capacitance elements 30a and 30b.

The capacitance/voltage conversion circuit 100a includes a first voltage applying unit 10, a second voltage applying unit 12, a first sample hold circuit 14, a second sample hold circuit 16, an amplification unit 20, a processing unit 22, a capacitor C12, a first switch SW1, and a second switch SW2. With the present embodiment, each of the first switch SW1 through the sixth switch SW6 is provided in the form of a transfer gate that employs a transistor.

The capacitance/voltage conversion circuit 100a converts the difference in the electrostatic capacitance between the first capacitor and the second capacitor while repeatedly switching the state between a first state and a second state.

The first voltage applying unit 10 is a circuit that applies a predetermined voltage to the variable capacitance element 30a connected as the first capacitor. During a period of time when a first control signal SIG1 is in the high level state, the first voltage applying unit 10 outputs a first driving voltage Vdrv1 which is the input voltage. On the other hand, during a period of time when the first control signal SIG1 is in the low level state, the first voltage applying unit 10 sets the output terminal to the high impedance state. In the first state, the first driving voltage Vdrv1 is set to a predetermined first fixed voltage. On the other hand, in the second state, the first driving voltage Vdrv is set to a second fixed voltage that is lower than the first fixed voltage. With the present embodiment, the first fixed voltage is set to the power supply voltage Vdd. On the other hand, the second fixed voltage is set to the ground voltage 0 V.

The second voltage applying unit 12 is a circuit that applies a predetermined voltage to the variable capacitance element 30b connected as the second capacitor. During a period of time when a second control signal SIG2 is in the high level state, the second voltage applying unit 12 outputs a second driving voltage Vdrv2. On the other hand, during a period of time when the second control signal SIG2 is in the low level state, the second voltage applying unit 12 sets the output terminal to the high impedance state. In the first state, the second driving voltage Vdrv2 is set to the second fixed voltage, i.e., the ground voltage 0V. On the other hand, in the second state, the second driving voltage Vdrv is set to the first fixed voltage, i.e., the power supply voltage Vdd.

That is to say, the first voltage applying unit 10 applies the first fixed voltage to the variable capacitance element 30a in the first state, and applies the second fixed voltage to the variable capacitance element 30a in the second state. On the other hand, the second voltage applying unit 12 applies the second fixed voltage to the variable capacitance element 30b in the first state, and applies the first fixed voltage to the variable capacitance element 30b in the second state. As described above, the respective voltages are applied to the variable capacitance elements 30a and 30b with the phases inverted to each other in a waveform in which the voltage level switches according to the switching between the first state and the second state.

The first switch SW1 and the second switch SW2 are provided between the first detection terminal 102 and the second detection terminal 104 to which the variable capacitance elements 30a and 30b are connected. Upon turning on both the first switch SW1 and the second switch SW2, the terminal of the first capacitor and the terminal of the second capacitor are connected to each other. This leads to a state that allows the charge stored in the variable capacitance elements 30a and 30b to flow through the path between the capacitors, thereby averaging the voltages at the first and second capacitors.

In the first state, the first sample hold circuit 14 averages the voltages Vx1 and Vx2 at the variable capacitance elements 30a and 30b which serve as the first capacitor and the second capacitor. Then, the first sample hold circuit 14 holds the voltage thus averaged as a first detection voltage Vdet1.

The first sample hold circuit 14 includes a third switch SW3, a fourth switch SW4, and a capacitor C10. Upon turning on the third switch SW3, the average voltage of the voltages Vx1 and Vx2 is sampled as the first detection voltage Vdet1. Then, upon turning off the third switch SW3, the first detection voltage Vdet thus sample is held.

On the other hand, in the second state, the second sample hold circuit 16 averages the voltages Vx1 and Vx2 at the variable capacitance elements 30a and 30b which serve as the first capacitor and the second capacitor. Then, the first sample hold circuit 14 holds the voltage thus averaged as a second detection voltage Vdet2. The second sample hold circuit 16 has the same configuration as that of the first sample hold circuit 14.

The amplification unit 20 is a differential amplifier which receives the first detection voltage Vdet1 and the second detection voltage Vdet2 as the input signals, and which amplifies the difference between the two voltages. A capacitor 12 is provided between the differential input terminals of the amplification unit 20. The voltage amplified by the amplification unit 20 is input to the processing unit 22.

The processing unit 22 performs analog/digital conversion processing for the detection voltage Vdet output from the amplification unit 20, and performs predetermined processing for the signal thus converted. Then, the processing unit 22 outputs the signal thus processed via the output terminal 106 in the form of digital data Dx.

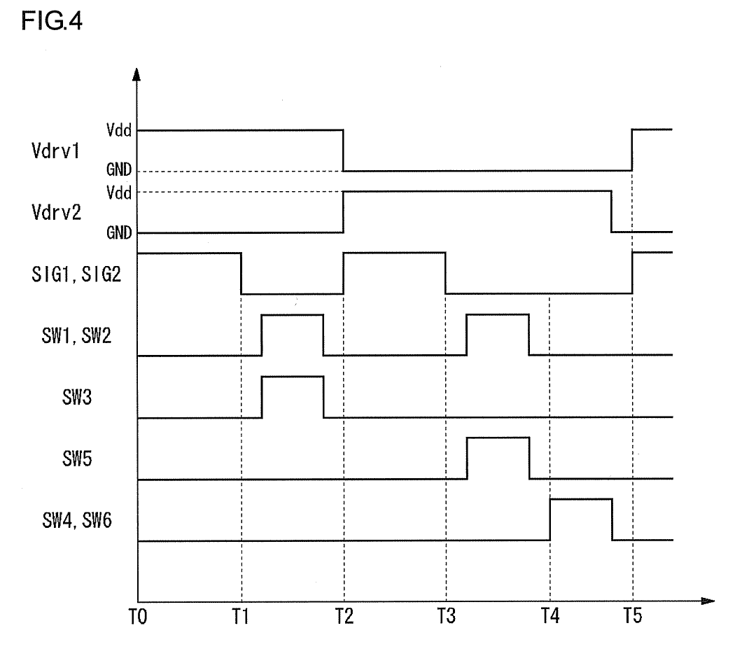

Description will be made regarding the operation of the capacitance/voltage conversion circuit 100a having the above-described configuration. FIG. 4 is an operation waveform diagram for the capacitance/voltage conversion circuit 100a. FIG. 4 shows the waveform of the first driving voltage Vdrv1, the waveform of the second driving voltage Vdrv2, the waveform of the first control signal SIG1, the waveform of the second control signal SIG2, and the waveforms that indicate the ON/OFF states of the first switch SW1 through the sixth switch SW6, in that order from the top of the drawing. In FIG. 4, the ON state of each of the switches SW1 through SW6 corresponds to the high level state. On the other hand, the OFF state of each of the switches SW1 through SW6 corresponds to the low level state. Also, in FIG. 4, the period from the point in time T0 up to the point in time T2 corresponds to the first state. On the other hand, the period from the point in time T2 up to the point in time T4 corresponds to the second state.

During the first state from the point in time T0 up to the point in time T2, the first driving voltage Vdrv1, which is input to the first voltage applying unit 10, is set to the power supply voltage Vdd. On the other hand, the second driving voltage Vdrv2, which is input to the second voltage applying unit 12, is set to the ground voltage, i.e., 0 V.

Furthermore, during the period of time from the point in time T0 up to the point in time T1, each of the first control signal SIG1 and the second control signal SIG2 is set to the high level state. As a result, the variable capacitance element 30a is charged with the first driving voltage Vdrv1 which has been set to the Vdd. On the other hand, the variable capacitance element 30b is charged with the second driving voltage Vdrv2 which has been set to 0 V. After the charge, the variable capacitance elements 30a and 30b exhibit the voltages Vx1=Vdd and Vx2=0 V, respectively.

At the point in time T1, each of the first control signal SIG1 and the second control signal SIG2 is switched to the low level state, which stops application of voltage to the variable capacitance elements 30a and 30b. In this state, with the electrostatic capacitance of the variable capacitance element 30a as Cx1, and with the electrostatic capacitance of the variable capacitance element 30b as Cx2, the charges stored in the variable capacitance elements 30 are represented by Expressions Q1=Cx1×Vdd, and Q2=Cx2×0.

Then, the first switch SW1 and the second switch SW2 are turned on. This switching leads to a state that allows the charge stored in the variable capacitance elements 30a and 30b to flow through the path therebetween, thereby averaging the voltages Vx1 and Vx2 at the variable capacitance elements 30. The voltage Vx thus averaged is represented by Expression Vx=(Q1+Q2)/(Cx1+Cx2)=Cx1×Vdd/(Cx1+Cx2).

Also, the third switch SW3 is turned on at the same time of the switching of the first switch SW1 and the second switch SW2. Accordingly, the first sample hold circuit 14 samples and holds the averaged voltage Vx as the first detection voltage Vdet1.

At the point in time T2, the state is switched to the second state. During the second state from the point in time T2 up to the point in time T4, the first driving voltage Vdrv1, which is input to the first voltage applying unit 10, is set to the ground voltage, i.e., 0 V. On the other hand, the second driving voltage, which is input to the second voltage applying unit 12, is set to the power supply voltage Vdd.

Each of the first control signal SIG1 and the second control signal SIG2 is switched to the high level state again during a period from the point in time T2 up to the point in time T3. As a result, the variable capacitance element 30a is charged with the first driving voltage Vdrv1 which has been set to the ground voltage, i.e., 0 V. On the other hand, the variable capacitance element 30b is charged with the second driving voltage Vdrv2 which has been set to Vdd. After the charge, the variable capacitance elements 30a and 30b exhibit the voltages Vx1=0 and Vx2=Vdd, respectively.

At the point in time T3, each of the first control signal SIG1 and the second control signal SIG2 is switched to the low level state, which stops application of voltage to the variable capacitance elements 30a and 30b. In this state, the charges stored in the variable capacitance elements 30 are represented by Expressions Q1=Cx1×0 V, and Q2=Cx2×Vdd.

Next, the first switch SW1 and the second switch SW2 are turned on. This switching leads to a state that allows the charge stored in the variable capacitance elements 30a and 30b to flow through the path therebetween, thereby averaging the voltages Vx1 and Vx2 at the variable capacitance elements 30. The voltage Vx thus averaged is represented by Expression Vx=(Q1+Q2)/(Cx1+Cx2)=Cx2×Vdd/(Cx1+Cx2).

Also, the fifth switch SW5 is turned on at the same time of the switching of the first switch SW1 and the second switch SW2. Accordingly, the second sample hold circuit 16 samples and holds the averaged voltage Vx as the second detection voltage Vdet2.

At the point in time T4, the fourth switch SW4 and the sixth switch SW6 are turned on. In this state, the first sample hold circuit 14 and the second sample hold circuit 16 output the first detection voltage Vdet1 and the second detection voltage Vdet2 thus sampled and held, to the amplification unit 20.

The amplification unit 20 performs differential amplification of the first detection voltage Vdet1 and the second detection voltage Vdet2. With the differential amplification gain of the amplification unit 20 as Av, the output voltage Vout of the amplification unit 20 is represented by Expression Vout=Av×(Vdet1−Vdet2)=Av×Vdd×(Cx1−Cx2)/(Cx1+Cx2).

At the point in time T5, the state is returned to the first state again. Then, the same operation is performed, thereby performing capacitance/voltage conversion again.

The output voltage Vout of the amplification unit 20 is obtained by amplifying the difference in the electrostatic capacitance between the first capacitor and the second capacitor connected to the first detection terminal 102 and the second detection terminal 104. As described above, the capacitance/voltage conversion circuit 100a according to the present embodiment provides a function of detecting the difference between the two electrostatic capacitances in an amplified form.

Now, let us say that the variable capacitance elements 30a and 30b have the same electrostatic capacitance Cx before pressure is applied. Upon the user pressing the left side of the cover 50, there is an increase only in the electrostatic capacitance of the variable capacitance element 30a while the electrostatic capacitance of the variable capacitance element 30b remains at the initial value. Here, with the change in the electrostatic capacitance of the variable capacitance element 30a as ΔCx, the capacitance of the variable capacitance element 30a thus increased is represented by Expression Cx1=Cx+ΔCx.

The Expression Cx1=Cx+ΔCx is substituted into the aforementioned Expression that represents the output voltage Vout, thereby obtaining Expression Vout=Av×Vdd×ΔCx/(Cx1+Cx2). The value Vout is proportional to ΔCx, which is the change in the electrostatic capacitance of the variable capacitance element 30a, and accordingly, the value Vout is proportional to change in the distance between the electrodes thereof. Accordingly, such an arrangement provides a function of detecting the magnitude of the pressure applied to the cover 50 by the user.

In the same way as described above, the capacitance/voltage conversion circuit 100b shown in FIG. 2 detects the difference in the electrostatic capacitance between the variable capacitance elements 30c and 30d disposed at the upper side and the lower side.

As described above, the input device 220 that employs the capacitance/voltage conversion circuits 100a and 100b according to the present embodiment provides a function of detecting the direction where the pressure has been applied, which is selected from among the left side, the right side, the upper side, and the lower side, and detecting the magnitude of the pressure thus applied, with high sensitivity. Thus, such an arrangement provides an input device with improved operability. With such an arrangement, the detection sensitivity can be increased by increasing the amplification factor Av of the amplification unit 20, thereby enabling a minute change in the electrostatic capacitance to be detected. Such an arrangement reduces the electrode area of each of the variable capacitance elements 30a through 30d, thereby providing a small-size cellular phone terminal 200.

### Second Embodiment

Description has been made in the first embodiment regarding an arrangement in which the four variable capacitance elements 30a through 30d are assigned to two groups, i.e., a group for detecting the pressure applied to the upper side or the lower side, a group for detecting the pressure applied to the left side or the right side. With such an arrangement, the difference in electrostatic capacitance is detected between the capacitors forming a capacitor pair. With the input device 220 having such a configuration, let us consider a case in which pressure is applied to the entire region including the variable capacitance elements 30a through 30d. In this case, a pair of the variable capacitance element 30a and 30b, or a pair of the variable capacitance element 30c and 30d, exhibits the same change in the electrostatic capacitance. Accordingly, with such an arrangement, in this case, the state due to the application of the pressure cannot be detected in increments of the variable capacitance elements 30. On the other hand, description will be made in a second embodiment regarding an input device 220 that provides a function of separately detecting change in the electrostatic capacitance in increments of variable capacitance elements 30a through 30d.

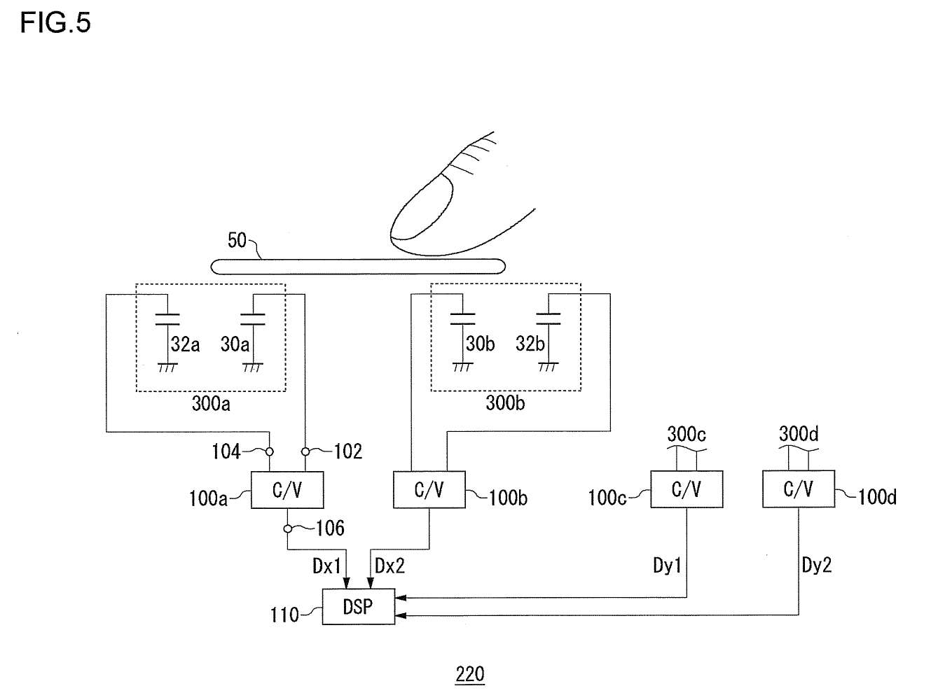

FIG. 5 shows a configuration of the input device 220 according to the second embodiment. The input device 220 according to the present embodiment includes the variable capacitance elements 30a through 30d, reference capacitors 32a through 32d, the capacitance/voltage conversion circuits 100a through 100d, and the DSP 110.

The variable capacitance elements 30a through 30d are disposed at four positions that correspond to the upper side, the lower side, the left side, and the right side of the input device 220, respectively, in the same way as with the input device 220 according to the first embodiment shown in FIG. 2. FIG. 5 shows the two variable capacitance elements 30a and 30b that correspond to the left side and the right side.

The reference capacitors 32a through 32d are provided for the variable capacitance elements 30a through 30d, respectively. Each of the reference capacitor 32a through 32d has fixed electrostatic capacitance. Accordingly, application of pressure to any side of the cover 50 does not change the electrostatic capacitance of each of the reference capacitors 32a through 32d. Here, the electrostatic capacitance of each of the reference capacitors 32a through 32d is set to the capacitance of the variable capacitance elements 30a through 30d in the initial state, i.e., in the state before the pressure is applied.

The variable capacitance element 30a and the reference capacitor 32a form a capacitor pair 300a. The capacitance/voltage conversion circuit 100a detects the difference in electrostatic capacitance between the capacitor pair 300a. Also, the variable capacitance element 30b and the reference capacitor 32b form a capacitor pair 300b. Also, the variable capacitance element 30c and the reference capacitor 32c form a capacitor pair 300c. Also, the variable capacitance element 30d and the reference capacitor 32d form a capacitor pair 300d. With such an arrangement, the capacitance/voltage conversion circuits 100b, 100c, and 100d detect the difference in electrostatic capacitance between the capacitor pair 300b, the difference in electrostatic capacitance between the capacitor pair 300c, and the difference in electrostatic capacitance between the capacitor pair 300d, respectively.

Each of the reference capacitors 32a through 32d has the fixed electrostatic capacitance. Furthermore, the electrostatic capacitance of each of the reference capacitors 32 is the same as that of each of the variable capacitance elements 30 in the initial state. Accordingly, each of the capacitance/voltage conversion circuits 100 according to the present embodiment detects the difference in electrostatic capacitance, which indicates the change in electrostatic capacitance of the corresponding variable capacitance element 30, i.e., which indicates the magnitude of the pressure applied by the user.

The capacitance/voltage conversion circuits 100a through 100d output the changes in electrostatic capacitance thus detected to the DSP 110 in the form of digital data sets Dx1, Dx2, Dy1, and Dy2.

The capacitance/voltage conversion circuits 100a through 100d have the same configuration and the same operation as those of the capacitance/voltage conversion circuits 100 according to the first embodiment.

The input device 220 according to the present embodiment detects each difference between the variable capacitance 30 and the corresponding reference capacitor 32, i.e., the difference between the variable capacitance element 30a and the corresponding reference capacitor 32a through the difference between the variable capacitance element 30d and the corresponding reference capacitor 32d. Such an arrangement enables the magnitude of the pressure applied to the left side, the right side, the upper side, and the lower side, to be detected separately in the form of the digital data sets Dx1, Dx2, Dy1, and Dy2. Let us consider a case in which the user applies the pressure to the entire region of the cover 50, which leads to a state in which there is change in the electrostatic capacitance for all the variable capacitance elements 30a through 30d. The input device 220 according to the present embodiment has a function of detecting even such a state.

The input device 220 having such a configuration can provides various kinds of processing. For example, an arrangement may be made in which the pressing of the variable capacitance elements 30a through 30d uniformly is assigned by the DSP 110 to a click operation which indicates the user finalizing the input data.

### Third Embodiment

An input device according to a third embodiment is a touch pad type input device.

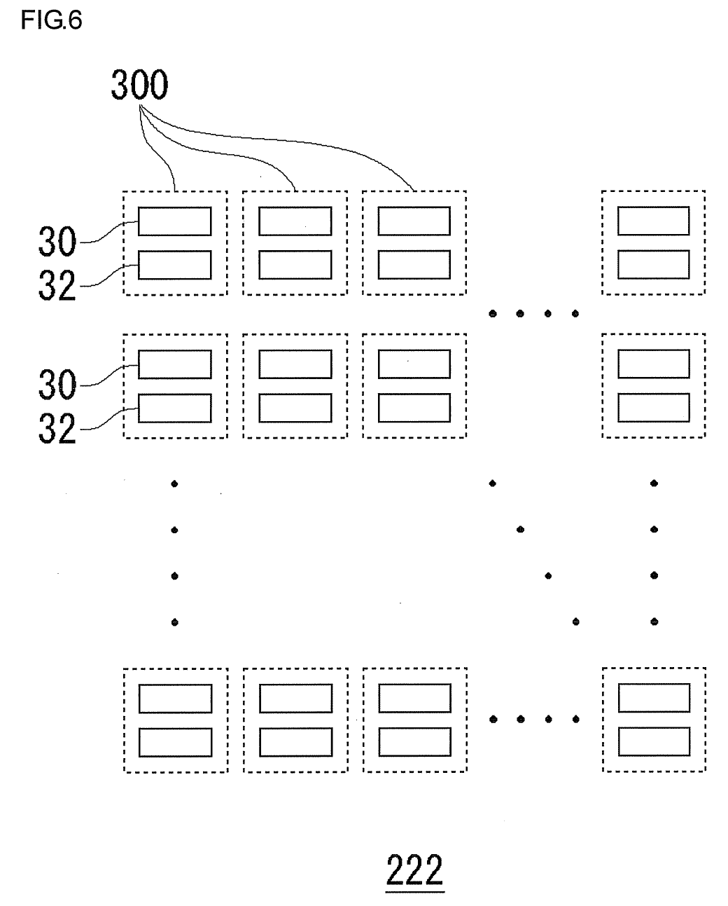

FIG. 6 is a diagram which shows a layout of capacitor pairs of an input device 222 according to the third embodiment. The input device 222 according to the third embodiment includes multiple capacitor pairs 300 disposed in the form of a matrix. Each capacitor pair 300 comprises a variable capacitance element 30 and a reference capacitor 32 in the same way as with the input device 220 according to the second embodiment. An unshown cover 50 is provided so as to cover the upper faces of these capacitor pairs 300 in the same way as with the input device 220 shown in FIG. 5.

Each capacitor pair 300 is connected to a corresponding one of multiple unshown capacitance/voltage conversion circuits 100. Each capacitance/voltage conversion circuit 100 detects the difference in electrostatic capacitance between the variable capacitance element 30 and the reference capacitor 32 included in the corresponding capacitor pair 300 thus connected.

Upon the user touching any region in the cover 50 via his/her finger, the variable capacitance elements 30, included in the capacitor pairs 300 that correspond to the region where the user has touched, are pressed. The capacitance/voltage conversion circuits 100 detect the magnitude of the pressure thus applied, in increments of the capacitor pairs 300.

The input device 222 according to the present embodiment provides a function of detecting change in electrostatic capacitance with high sensitivity for each variable capacitance element 30. Such an arrangement provides a function of detecting the magnitude of the pressure thus applied by the user, in addition to a function of detecting the variable capacitance elements 30 thus pressed by the user.

Furthermore, with the input device 222 according to the present embodiment, each capacitance/voltage conversion circuit 100 has a function of detecting the change in electrostatic capacitance with high sensitivity. Such an arrangement enables each variable capacitance element 30 to be designed with a reduced size, i.e., enables each electrode pair to be designed with a reduced area.

The above-described embodiments have been described for exemplary purposes only, and are by no means intended to be interpreted restrictively. Rather, it can be readily conceived by those skilled in this art that various modifications may be made by making various combinations of the aforementioned components or processes, which are also encompassed in the technical scope of the present invention.

Description has been made in the embodiment regarding an arrangement in which the capacitance/voltage conversion circuits 100 are applied to an input device that detects change in electrostatic capacitance. The application of the electrostatic/voltage conversion circuits 100 is not restricted to such an arrangement. For example, the electrostatic/voltage conversion circuit 100 may be applied to a microphone such as a capacitor-type microphone which has a structure having a capacitor formed of a diaphragm electrode and a back plate electrode, and which has a mechanism whereby, upon reception of sound pressure, the electrostatic capacitance of the capacitor changes.

Also, each capacitance/voltage conversion circuit 100 provides a function of amplifying and detecting an extremely small change in electrostatic capacitance. Thus, the capacitance/voltage conversion circuit 100 can be used in various kinds of applications.

Description has been made in the embodiment regarding an arrangement in which each capacitance/voltage conversion circuit 100 is integrally formed on a single semiconductor integrated circuit. However, the present invention is not restricted to such an arrangement. Also, each circuit block may provided in the form of a chip component or a discrete element. Which block is to be provided in the form of an integrated circuit should be decided based upon the employed semiconductor manufacturing process, required costs, properties, etc.

The input devices according to the embodiments can be applied to electronic devices including various kinds of input devices, such as personal computers, PDAs (Personal Digital Assistants), digital still cameras, remote controllers for CD players, etc., in addition to cellular phone terminals as described in the embodiments.

While the preferred embodiments of the present invention have been described using specific terms, such description is for illustrative purposes only, and it is to be understood that changes and variations may be made without departing from the spirit or scope of the appended claims.

1. A capacitance/voltage conversion circuit, which converts the difference in electrostatic capacitance between a first capacitor and a second capacitor into a voltage, comprising:
a first voltage applying unit which applies a predetermined first fixed voltage to said first capacitor during a first state, and which applies a predetermined second fixed voltage, which is lower than the first fixed voltage, to said first capacitor during a second state;
a second voltage applying unit which applies the second fixed voltage to said second capacitor during the first state, and which applies the first fixed voltage to said second capacitor during the second state;
a first sample hold circuit which averages the voltage at said first capacitor and the voltage at said second capacitor in the first state, and which holds the voltage thus averaged as a first detection voltage;
a second sample hold circuit which averages the voltage at said first capacitor and the voltage at said second capacitor in the second state, and which holds the voltage thus averaged as a second detection voltage; and
an amplification unit which amplifies the voltage difference between the first detection voltage and the second detection voltage.

2. A capacitance/voltage conversion circuit according to claim 1, wherein said amplification unit is a differential amplifier which receives the first detection voltage and the second detection voltage as the input signals.

3. A capacitance/voltage conversion circuit according to claim 1, wherein each of said first and said second sample hold circuits is configured to connect the terminals of said first capacitor and said second capacitor to each other, thereby averaging the voltage at said first capacitor and the voltage at said second capacitor.

4. A capacitance/voltage conversion circuit according to claim 1, wherein the second fixed voltage is ground voltage.

5. A capacitance/voltage conversion circuit according to claim 1, wherein the capacitance/voltage conversion circuit is integrated formed on a single semiconductor integrated circuit.

6. An input device comprising:
a first electrode pair and a second electrode pair each of which includes a pair of electrodes provided such that they face one another, and each of which has a mechanism whereby, upon application of pressure externally, the distance between the two electrodes changes, thereby exhibiting a change in electrostatic capacitance; and
a capacitance/voltage conversion circuit, which converts into a voltage the difference in electrostatic capacitance between said first electrode pair that serves as said first capacitor and said second electrode pair that serves as said second capacitor.

7. An input device comprising:
a first electrode pair, a second electrode pair, a third electrode pair, and a fourth electrode pair, each of which includes a pair of electrodes provided such that they face one another, and each of which has a mechanism whereby, upon application of pressure externally, the distance between the two electrodes changes, thereby exhibiting a change in electrostatic capacitance;
a first capacitance/voltage conversion circuit, which converts into a voltage the difference in electrostatic capacitance between said first electrode pair that serves as said first capacitor and said second electrode pair that serves as said second capacitor;
a second capacitance/voltage conversion circuit, which converts into a voltage the difference in electrostatic capacitance between said third electrode pair that serves as said first capacitor and said fourth electrode pair that serves as said second capacitor; and
a cover which is provided so as to cover said first electrode pair through said fourth electrode pair, and which has a configuration that allows a user to press said cover externally,
wherein said first electrode pair through said fourth electrode pair are provided at four positions that correspond to the upper portion, the lower portion, the left portion, and the right portion.

8. An input device comprising:
a plurality of electrode pairs each of which includes a pair of electrodes provided such that they face one another, and each of which has a mechanism whereby, upon application of pressure externally, the distance between the two electrodes changes, thereby exhibiting a change in electrostatic capacitance;
a plurality of reference capacitors which are each provided to said plurality of electrode pairs, and each of which has a fixed electrostatic capacitance; and
a plurality of capacitance/voltage conversion circuits, each of which is provided to a corresponding capacitor pair including said electrode pair and said reference capacitor, and each of which converts into a voltage the difference in electrostatic capacitance between said electrode pair that serves as said first capacitor and said reference capacitor that serves as said second capacitor.

9. An input device according to claim 8, wherein the number of said capacitor pairs, each of which includes said electrode pair and said reference capacitor, is four,
and wherein said four capacitor pairs are provided at four portions that correspond to the upper portion, the lower portion, the left portion, and the right portion,
and wherein a cover is provided so as to cover said four capacitor pairs, and which has a configuration that allows a user to press said cover externally.

10. An input device according to claim 8, wherein said capacitor pairs, each of which includes said electrode pair and said reference capacitor, are disposed in the form of a matrix,
and wherein a cover is provided so as to cover said plurality of capacitor pairs, and which has a configuration that allows a user to press said cover externally.

11. An electronic device comprising an input device according to claim 8.

12. A capacitance/voltage conversion method comprising:
a first step in which a first capacitor is charged with a first fixed voltage, and a second capacitor is charged with a second fixed voltage;
a step in which the voltage at said first capacitor and the voltage at said second capacitor in said first step are averaged, and the voltage thus averaged is held as a first detection voltage;
a second step in which said first capacitor is charged with the second fixed voltage, and said second capacitor is charged with the first fixed voltage;
a step in which the voltage at said first capacitor and the voltage at said second capacitor in said second step are averaged, and the voltage thus averaged is held as a second detection voltage; and
a step for amplifying the difference between the first detection voltage and the second detection voltage.

13. A capacitance/voltage conversion method according to claim 12, wherein the charge stored in said two capacitors is averaged, thereby averaging the voltage at said first capacitor and the voltage at said second capacitor.

14. A capacitance/voltage conversion method according to claim 12, wherein the second fixed voltage is ground voltage.
